(19) United States
(12) Patent Application Publication
(10) Pub. No.: US 2011/0141830 A1
(43) Pub. Date: Jun. 16, 2011

(54) SEMICONDUCTOR MEMORY DEVICE AND METHOD FOR OPERATING THE SAME

(76) Inventors: Sung-Soo CHI, Gyeonggi-do (KR); Ki-Chang Kwean, Gyeonggi-do (KR)

(21) Appl. No.: 12/648,574

(22) Filed: Dec. 29, 2009

(30) Foreign Application Priority Data
Dec. 11, 2009 (KR) 10-2009-0123196

(51) Int. Cl. G11C 7/00; G11C 5/14; G11C 7/02

(52) U.S. Cl. 365/189.11; 365/226; 365/207

(57) ABSTRACT

A semiconductor memory device includes a sense amplifier configured to sense and amplify data loaded into a bit line pair, a power line equalize signal generation unit configured to generate a power line equalize signal which is activated until the bit line sense amplifier is enabled after a bit line equalize signal is deactivated, a power line equalizing unit configured to supply a precharge voltage to a pull-up power line and a pull-down power line of the bit line sense amplifier when the power line equalize signal is activated, a pull-up driving unit configured to drive the pull-up power line of the bit line sense amplifier to a pull-up voltage, and a pull-down driving unit configured to drive the pull-down power line of the bit line sense amplifier to a pull-down voltage.

### CROSS-REFERENCE TO RELATED APPLICATIONS

The present application claims priority of Korean Patent Application No. 10-2009-0123196, filed on Dec. 11, 2009, which is incorporated herein by reference in its entirety.

### BACKGROUND OF THE INVENTION

Exemplary embodiments of the present invention relate to a semiconductor design technology, and more particularly, to a bit line sense amplifier of a semiconductor memory device.

To read bit data stored in each memory cell of a semiconductor memory device, specifically Dynamic Random Access Memory (DRAM), weak energy of the data stored in the memory cell should be amplified. In this case, a bit line sense amplifier is required for the amplification.

The bit line sense amplifier has an offset potential difference due to various causes, such as a threshold voltage difference between Metal Oxide Semiconductor (MOS) transistors, a transconductance difference, and a capacitance difference between a bit line and a bar bit line. When cell data is applied to a bit line, a variation in potential difference, although small, is significant. Further, when the bit line sense amplifier has an offset voltage, a loss occurs by the offset voltage during the amplification operation. In a case of Double-Data-Rate3 Synchronous Dynamic Random Access Memory (DDR3 SDRAM), the bit line sense amplifier should amplify a very minute signal of 180 mV. Therefore, when it is assumed that the bit line sense amplifier has an offset potential of 100 mV, the bit line sense amplifier should amplify the signal in response to a potential difference of 80 mV. This means that a loss of 100 mV corresponding to the offset potential occurs during the amplification operation of the sense amplifier.

FIG. 1 is a circuit diagram illustrating a conventional bit line sense amplifier and a peripheral area thereof.

Referring to FIG. 1, the peripheral area of the bit line sense amplifier 10 includes a pull-up driving unit 11, a pull-down driving unit 12, a power line equalizing unit 13, a bit line equalizing unit 14, a bit line precharge unit 15, a bit line separation unit 16, and a bit line equalization bar signal generation unit 17. The pull-up driving unit 11 is configured to supply a pull-up voltage to a pull-up power line RT0 of the bit line sense amplifier 10. The pull-down driving unit 12 is configured to supply a pull-down voltage to a pull-down power line SB of the bit line sense amplifier 10. The power line equalizing unit 13 is configured to equalize the pull-up and pull-down power lines RT0 and SB of the bit line sense amplifier 10 to a precharge voltage VBLP. The bit line equalizing unit 14 is configured to equalize a bit line BL and a bar bit line BLB. The bit line precharge unit 15 is configured to supply a precharge voltage VBLP to the bit line BL and the bar bit line BLB. The bit line separation unit 16 is configured to select any one of upper and lower cell arrays of the bit line sense amplifier 10 in response to bit line separation signals BISH and BISL, respectively. The pull-up driving unit 11 includes an overdriving unit 111 configured to overdrive the pull-up power line RT0 of the bit line sense amplifier 10 with a power supply voltage VDD, and a normal driving unit 112 configured to normally drive the pull-up power line RT0 of the bit line sense amplifier 10 with a core voltage VCORE.

FIG. 2 is a timing diagram of various control signals of the bit line sense amplifier shown in FIG. 1.

Referring to FIGS. 1 and 2, the operation of the bit line sense amplifier will be described.

When a bit line equalization bar signal BLEQB passes through an inverter INV, a bit line equalize signal BLEQ is generated. The bit line equalize signal BLEQ equalizes the bit line BL and the bar bit line BLB and is disabled at a certain time before the bit line sense amplifier 10 operates. When the bit line equalize signal BLEQ is disabled, the bit line BL and the bar bit line BLB are separated from each other such that a potential difference between both of the lines is caused by the potential of a cell capacitor and a charge sharing effect.

An overdriving signal SAP1 is a signal directing the overdriving unit 111 to overdrive the bit line sense amplifier 10. More specifically, the overdriving signal SAP1 drives the pull-up power line RT0 of the bit line sense amplifier 10 to the power supply voltage VDD. A normal driving signal SAP2 is a signal directing the normal driving unit 112 to normally drive the bit line sense amplifier 10. More specifically, the normal driving signal SAP2 drives the pull-up power line RT0 of the bit line sense amplifier 10 to the core voltage VCORE. A pull-down driving signal SAN is a signal directing the pull-down driving unit 12 to drive the pull-down power line SB of the bit line sense amplifier 10 to a ground voltage VSS. A bit line sense amplifier enable signal SAEN is a signal enabling the supply of a voltage to the pull-up power line RT0 and the pull-down power line SB of the bit line sense amplifier 10 to drive the bit line sense amplifier 10. In the case of FIG. 2, since the pull-down driving signal SAN is first activated, the bit line sense amplifier enable signal SAEN corresponds to the pull-down driving signal SAN.

When a word line is activated by an active signal to select a cell, electric charges of the cell capacitor are loaded into the bit line BL and the bar bit line BLB, which have been precharged, in the form of charge sharing. In this case, a potential difference occurs between the bit line BL and the bar bit line BLB. Then, when the sense amplifier driving signals SAP1, SAP2, and SAN are activated, the bit line sense amplifier 10 amplifies the potential difference between the bit line BL and the bar bit line BLB. When the bit line equalize signal BLEQ is activated after the amplification operation, the bit line BL and the bar bit line BLB are equalized to the precharge voltage VBLP. Furthermore, the power line equalizing unit 13 also equalizes the pull-up and pull-down power lines RT0 and SB of the bit line sense amplifier 10 to the precharge voltage VBLP in response to the bit line equalize signal BLEQ.

Referring to FIG. 2, a certain time difference tD exists between the point in time that the bit line sense amplifier 10 is enabled and the point in time that the bit line equalize signal BLEQ is disabled. This is because a time is needed, during which the electric charges of the cell capacitor are loaded into the bit line BL and the bar bit line BLB and the potential difference is caused by the charge sharing effect, after the word line is activated.

The power line equalizing unit 13 of the conventional bit line sense amplifier 10 is controlled by the bit line equalize signal BLEQ. Therefore, the pull-up and pull-down power lines RT0 and SB of the bit line sense amplifier 10 stay in a floating state for the time tD until the bit line sense amplifier 10 operates after the bit line equalize signal BLEQ is disabled. In the floating state, the potential difference of the pull-up and pull-down power lines RT0 and SB cannot be decided clearly. This causes a result in which a potential difference between the gate of each transistor of the bit line sense amplifier 10 and the pull-up and pull-down power lines RT0 and SB becomes obscure. Therefore, such an obscure potential difference causes an offset potential of the bit line sense amplifier 10, which makes it difficult to estimate quantitative data.

### SUMMARY OF THE INVENTION

Exemplary embodiments of the present invention are directed to a semiconductor memory device capable of preventing a floating state of pull-up and pull-down power lines of a bit line sense amplifier, and a method for operating the same.

In accordance with an embodiment of the present invention, a semiconductor memory device includes a sense amplifier configured to sense and amplify data loaded into a bit line pair, a power line equalize signal generation unit configured to generate a power line equalize signal which is activated until the bit line sense amplifier is enabled after a bit line equalize signal is deactivated, a power line equalizing unit configured to supply a precharge voltage to a pull-up power line and a pull-down power line of the bit line sense amplifier when the power line equalize signal is activated, a pull-up driving unit configured to drive the pull-up power line of the bit line sense amplifier to a pull-up voltage, and a pull-down driving unit configured to drive the pull-down power line of the bit line sense amplifier to a pull-down voltage.

In accordance with another embodiment of the present invention, a method for operating a semiconductor memory device includes equalizing pull-up and pull-down power lines of a bit line sense amplifier to a precharge voltage until a bit line sense amplifier enable signal is activated after a bit line equalize signal is deactivated, and applying a driving voltage to the pull-up and pull-down power lines of the bit line sense amplifier in response to the bit line sense amplifier enable signal, and sensing and amplifying a potential difference between a bit line and a bar bit line.

### BRIEF DESCRIPTION OF THE DRAWINGS

FIG. 1 is a circuit diagram illustrating a conventional bit line sense amplifier and a peripheral area thereof.

FIG. 2 is a timing diagram of various control signals of the conventional bit line sense amplifier shown in FIG. 1.

FIG. 3 is a circuit diagram illustrating a bit line sense amplifier and a peripheral area thereof in accordance with an embodiment of the present invention.

FIG. 4A is a diagram of a bit line equalization bar signal and first control signal generation unit.

FIG. 4B is a diagram of an overdriving signal generation unit.

FIG. 4C is a diagram of a normal driving signal generation unit.

FIG. 4D is a diagram of a pull-down driving signal and second control signal generation unit.

FIG. 5A is a diagram illustrating an implemented example of a power line equalize signal generation unit.

FIG. 5B is an operation timing diagram of the power line equalize signal generation unit of FIG. 5A.

FIG. 6 is a timing diagram of bit line sense amplifier control signals in accordance with the embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

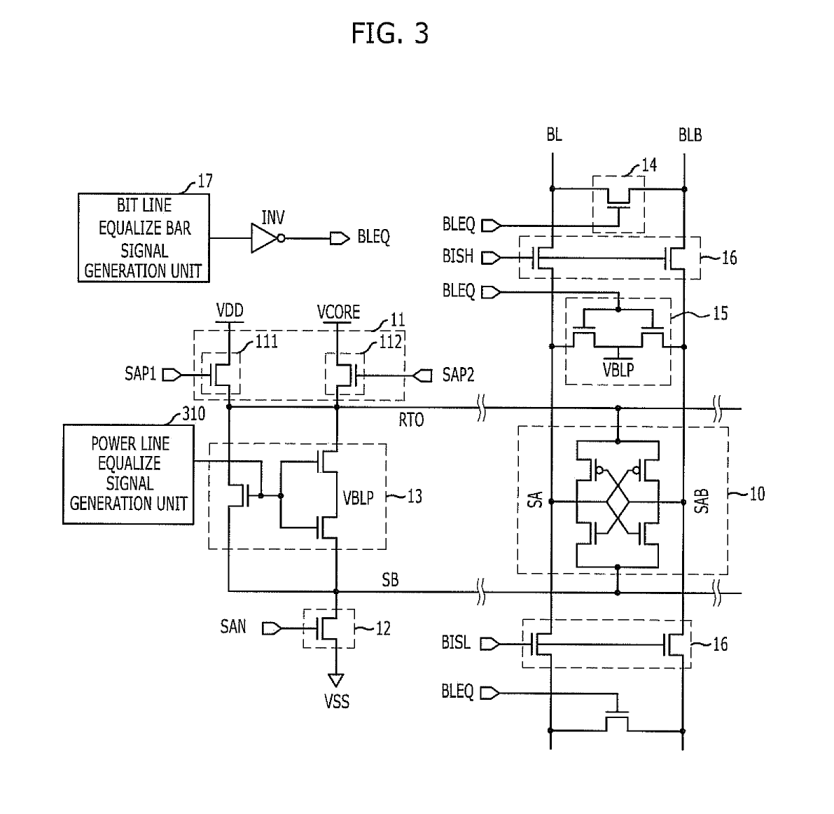

FIG. 3 is a circuit diagram illustrating a bit line sense amplifier and a peripheral area thereof in accordance with an embodiment of the present invention.

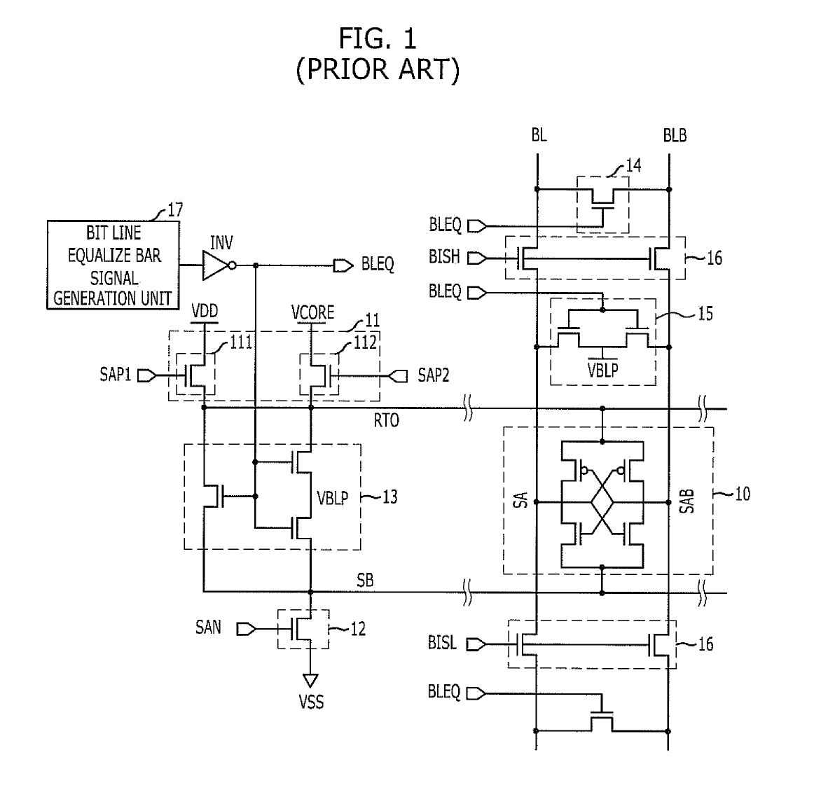

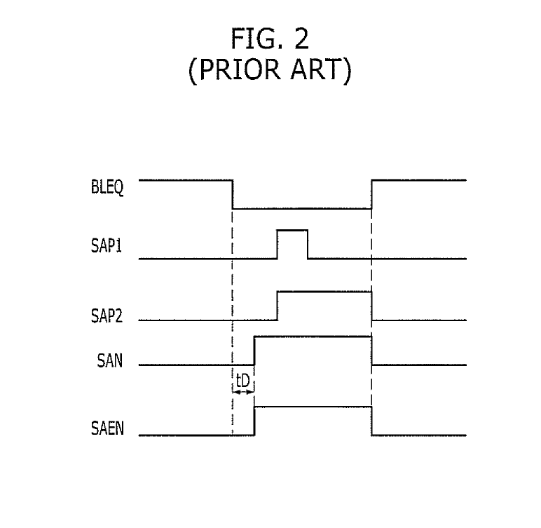

Referring to FIG. 3, the circuit diagram of the bit line sense amplifier 10 and the peripheral area thereof in accordance with the embodiment of the present invention is the same as that of the conventional bit line sense amplifier 10 and the peripheral area thereof illustrated in FIG. 1, except that a power line equalize signal generation 310 is added and an equalizing operation of power lines is controlled by a power line equalize signal PLEQ. The power line equalize signal PLEQ is a new control signal, replacing the bit line equalize signal BELQ, which controlled the equalizing operation of the power lines in the conventional bit sense amplifier 10.

Since the configuration and operation of the conventional bit line sense amplifier 10 and the peripheral area thereof have been described, the duplicated descriptions will be omitted.

The power line equalize signal PLEQ is activated at a point of time when the bit line equalize signal BLEQ is activated after the amplification operation of the bit line sense amplifier 10 is completed, and deactivated at a point of time when the bit line sense amplifier 10 operates (i.e., when any one of the driving signals SAP1, SAP2, and SAN of the bit line sense amplifier 10 is first activated).

Referring to FIG. 3, the pull-up power line RTO and the pull-down power line SB of the bit line sense amplifier 10 are equalized to the precharge VBLP during an activation interval of the power line equalize signal PLEQ.

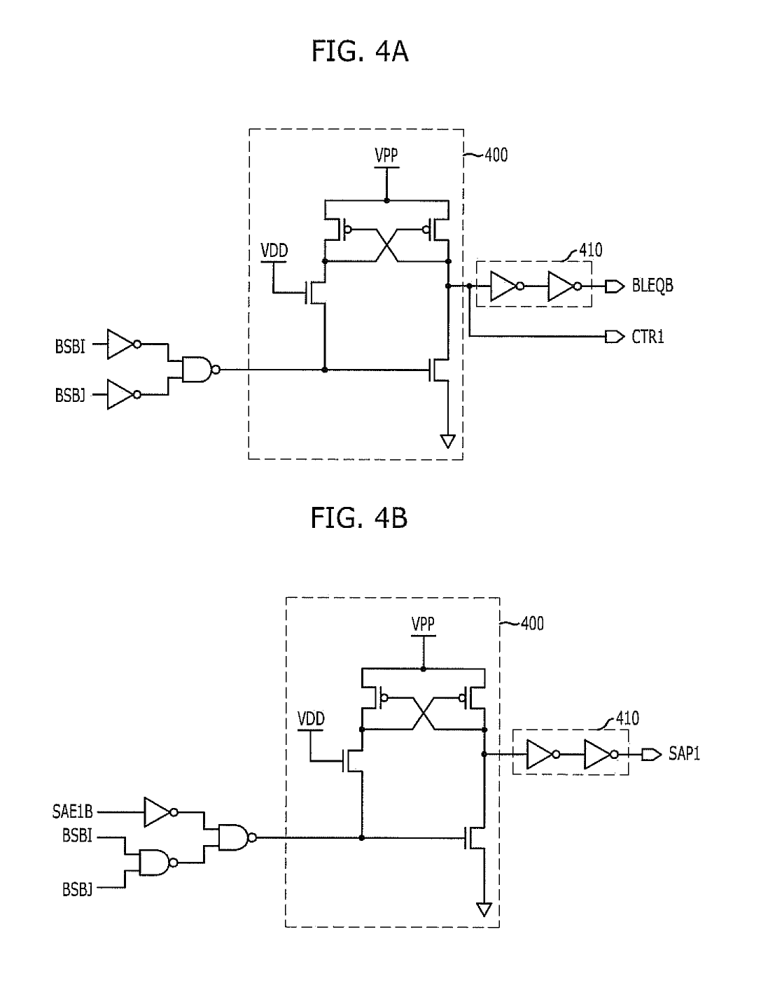

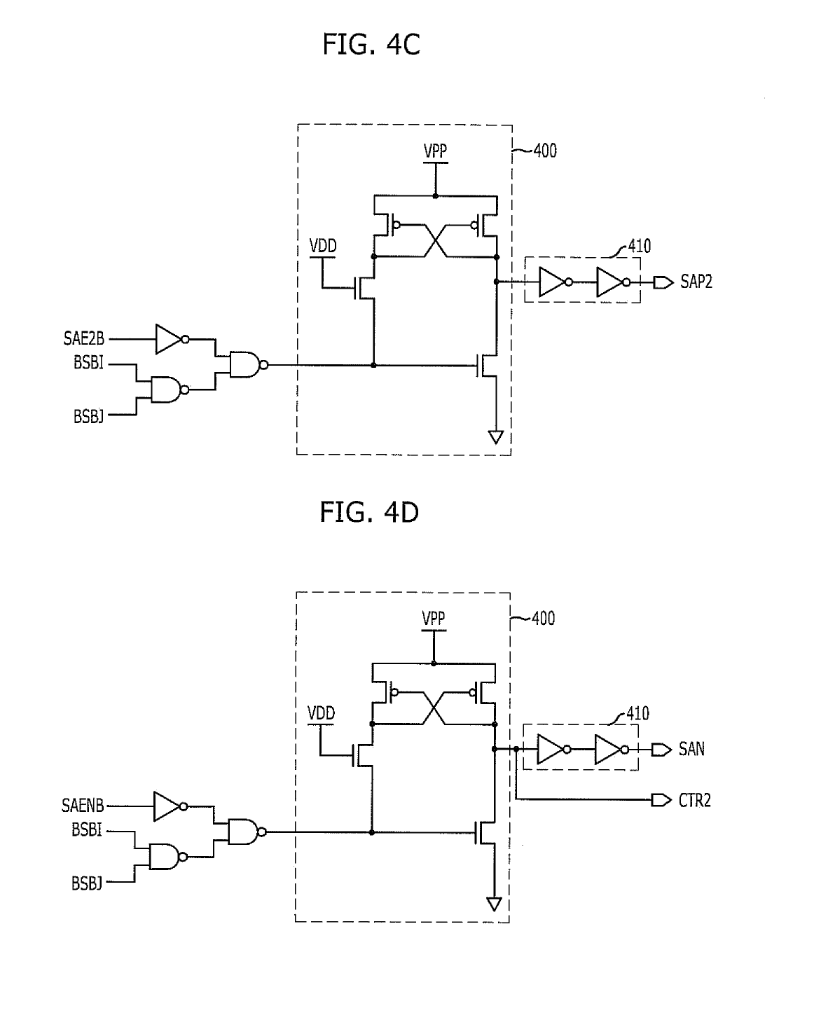

FIGS. 4A to 4D are diagrams illustrating signal generation units configured to drive the bit line sense amplifier 10 in accordance with the embodiment of the present invention. FIG. 4A is a diagram of a bit line equalization bar signal generation unit and first control signal generation unit, FIG. 4B is a diagram of an overdriving signal generation unit, FIG. 4C is a diagram of a normal driving signal generation unit, and FIG. 4D is a diagram of a pull-down driving signal and second control signal generation unit.

Referring to FIGS. 4A to 4D, the respective signal generation units include a level shifter 400 and have the same configuration, except that inputted signals and logic operation circuits acting on the inputted signals are different from one another. The respective signals are outputted through delay units 410 which are positioned at output terminals of the respective level shifters 400 and have the same configuration.

The operations of the respective generation units will be described in detail with reference to the respective drawings.

Referring to FIG. 4A, the bit line equalization bar signal generation unit is configured to receive a cell selection signal BSBI and a block selection signal BSBJ, perform a logic operation to obtain an operation result, transfer the operation result to the level shifter 400, and output a bit line equalization bar signal BLEQB through the delay unit 410 connected to the output terminal of the level shifter 400. The bit line equalization bar signal BLEQB is converted into a bit line equalize signal BLEQ through an inverter INV (not shown) to control the equalizing operation of the bit line BL and the bar bit line BLB. Furthermore, a first control signal is outputted from the output terminal of the level shifter 400.

Referring to FIG. 4B, the overdriving signal generation unit is configured to receive a first sense amplifier enable bar signal SAE1B corresponding to an inverted signal of an overdriving signal SAP1, a cell selection signal BSBI, and a block selection signal BSBJ. The overdriving signal generation unit is further configured to perform a logic operation to obtain an operation result, transfer the operation result to the level shifter 400, and output the overdriving signal SAP1 through the delay unit 410 connected to the output terminal of the level shifter 400.

Referring to FIG. 4C, the normal driving signal generation unit is configured to receive a second sense amplifier enable bar signal SAE2B corresponding to an inverted signal of a normal driving signal SAP2, a cell selection signal BSBI, and a block selection signal BSBJ. The normal driving signal generation unit is further configured to perform a logic operation to obtain an operation result, transfer the operation result to the level shifter 400, and output the normal driving signal SAP2 through the delay unit 410 connected to the output terminal of the level shifter 400.

Referring to FIG. 4D, the pull-down driving signal generation unit is configured to receive a sense amplifier enable bar signal SAENB corresponding to an inverted signal of a sense amplifier enable signal SAEN, a cell selection signal BSBI, and a block selection signal BSBJ. The pull-down driving signal generation unit is further configured to perform a logic operation to obtain an operation result, transfer the operation result to the level shifter 400, and output a pull-down driving signal SAN through the delay unit 410 connected to the output terminal of the level shifter 400. Furthermore, a second control signal is outputted from the output terminal of the level shifter 400.

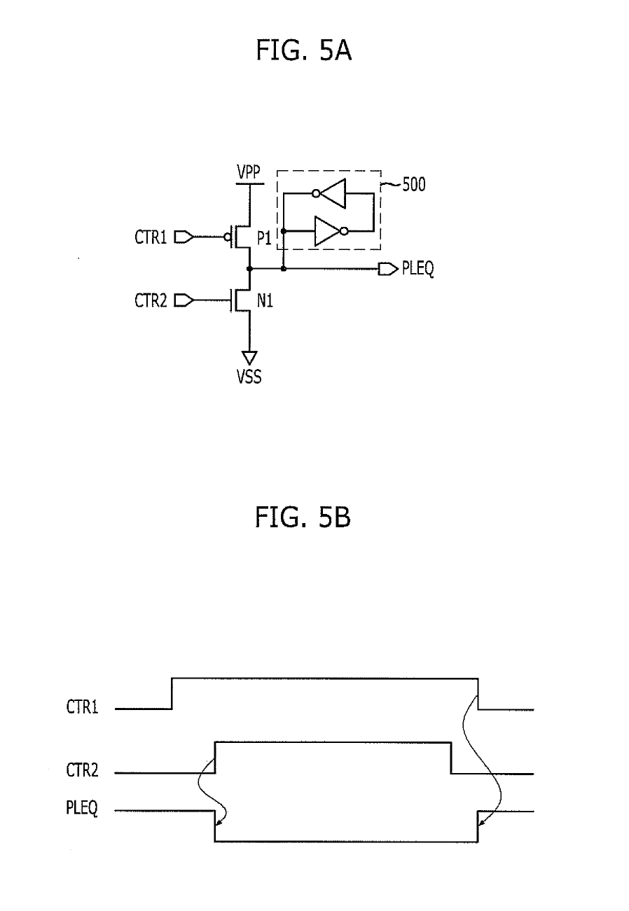

FIG. 5A is a diagram illustrating an implemented example of the power line equalize signal generation unit. FIG. 5B is an operation timing diagram of the power line equalize signal generation unit of FIG. 5A.

Referring to FIGS. 4A, 4B, 4C, 4D, 5A, and 5B, the operation of the power line equalize signal generation unit will be described.

When the pull-up power line RT0 and the pull-down power line SB of the bit line sense amplifier 10 are driven, DRAM controls the pull-up power line RT0 and the pull-down power line SB to be driven at different points of time. Hereafter, a case in which the pull-down power line SB is driven in advance of the pull-up power line RT0 will be described as an example. In this case, the pull-down driving signal SAN is activated in advance of the overdriving signal SAP1 and the normal driving signal SAP2. That is, the bit line sense amplifier enable signal SAEN corresponds to the pull-down driving signal SAN.

Referring to FIG. 5A, the power line equalize signal generation unit includes a PMOS transistor P1 configured to receive a first control signal CTR1 at the gate thereof, an NMOS transistor N1 configured to receive a second control signal CTR2 at the gate thereof, and a latch unit 500 connected to the drains of the PMOS and NMOS transistors. The drains of the PMOS and NMOS transistors are also coupled to output terminals.

Referring to FIG. 5B, the power line equalize signal PLEQ is synchronized to rise with a falling edge of the first control signal CTR1, and synchronized to fall with a rising edge of the second control signal CTR2.

Since the bit line equalization bar signal BLEQB is a signal obtained by delaying the first control signal CTR1, the first control signal CTR1 becomes a signal which leads the phase of the bit line equalization bar signal BLEQB by a certain time. Furthermore, since the pull-down driving signal SAN is a signal obtained by delaying the second control signal CTR2, the second control signal CTR2 becomes a signal which leads the phase of the pull-down driving signal SAN by a certain time. When the power line equalize signal generation unit receives the first and second control signals CTR1 and CTR2 to generate the power line equalize signal PLEQ, the phase of the power line equalize signal PLEQ is delayed. Therefore, when the power line equalize signal PLEQ is advanced by the delayed phase, the power line equalize signal PLEQ is synchronized to rise with the rising edge of the bit line equalize signal BLEQ, and synchronized to fall with the rising edge of the pull-down driving signal SAN.

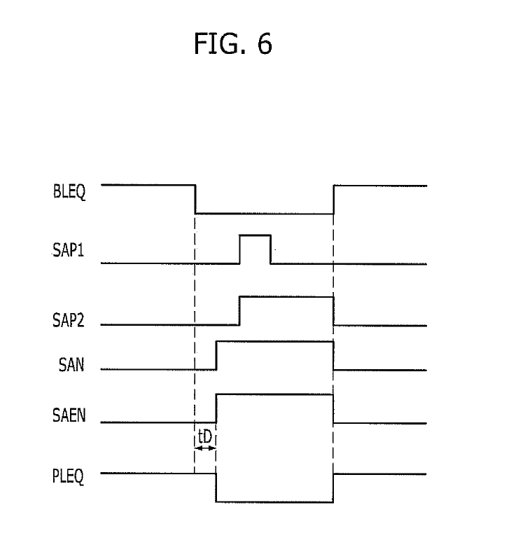

FIG. 6 is a timing diagram of the bit line sense amplifier control signals in accordance with the embodiment of the present invention.

In the conventional bit line sense amplifier 10, when the pull-up power line RT0 and the pull-down power line SB are equalized to the precharge voltage VBLP, the potentials of the pull-up power line RT0 and the pull-down power line SB are obscure during the time tD from a point of time when the bit line equalize signal BLEQ is disabled to a point of time when the bit line sense amplifier 10 is enabled. In this embodiment, however, the power line equalize signal PLEQ is used to apply the precharge voltage VBLP even during the time tD. Therefore, the voltages of the power lines RT0 and SB of the bit line sense amplifier 10 become clearly recognizable as the precharge voltage VBLP.

In the above-described embodiment, the case in which the pull-down driving signal SAN of the bit line sense amplifier 10 is activated in advance of the overdriving signal SAP1 and the normal driving signal SAP2 has been described as an example. However, since the technical principle of the present invention has no direct relation with the sequence of the pull-down driving signal SAN, the overdriving signal SAP, and the normal driving signal SAP2, the present invention may be applied to a case in which the overdriving signal SAP1 or the normal driving signal SAP2 is first activated. When the overdriving signal SAP1 is first activated, an output of the output terminal of the level shifter 400 of the overdriving signal generation unit may be applied to the gate of the NMOS transistor N1 of the power line equalize signal generation unit to perform the same operation.

In accordance with the embodiments of the present invention, it is possible to prevent the floating state from occurring when the pull-up and pull-down power lines of the bit line sense amplifier are equalized to a precharge voltage. Therefore, the offset potential of the bit line sense amplifier may be compensated for.

While the present invention has been described with respect to the specific embodiments, it will be apparent to those skilled in the art that various changes and modifications may be made without departing from the spirit and scope of the invention as defined in the following claims.

For example, the implemented example of the power-line equalize signal generation unit described in the above-described embodiment is only one of various implemented examples, and may be modified with other logic operators depending on the types and polarities of signals to be used.

What is claimed is:

1. A semiconductor memory device comprising:
a sense amplifier configured to sense and amplify data loaded from a bit line pair;
a power line equalize signal generation unit configured to generate a power line equalize signal which is activated until the bit line sense amplifier is enabled after a bit line equalize signal is deactivated;
a power line equalizing unit configured to supply a precharge voltage to a pull-up power line and a pull-down power line of the bit line sense amplifier when the power line equalize signal is activated;
a pull-up driving unit configured to drive the pull-up power line of the bit line sense amplifier to a pull-up voltage; and
a pull-down driving unit configured to drive the pull-down power line of the bit line sense amplifier to a pull-down voltage.

2. The semiconductor memory device of claim 1, wherein the pull-up driving unit comprises:
an overdriving unit configured to drive the pull-up power line to an overdriving voltage in response to an overdriving signal; and
a normal driving unit configured to drive the pull-up power line to a normal driving voltage in response to a normal driving signal.

3. The semiconductor memory device of claim 1, wherein the bit line sense amplifier is enabled at a point of time when any one of the overdriving unit, the normal driving unit, and the pull-down driving unit is first enabled.

4. The semiconductor memory device of claim 1, wherein the power line equalize signal generation unit comprises:
a PMOS transistor configured to receive a first control signal at a gate thereof;
an NMOS transistor configured to receive a second control signal at a gate thereof; and
a latch unit commonly connected to drains of the PMOS transistor and the NMOS transistor, the drains being coupled to output terminals.

5. The semiconductor memory device of claim 4, wherein the first control signal is an output signal of a level shifter of a bit line equalization bar signal generation unit, and leads a bit line equalization bar signal, which is an inverse of the bit line equalize signal, by a certain time.

6. The semiconductor memory device of claim 4, wherein the second control signal is an output signal of a level shifter of a pull-down driving signal generation unit, and leads a pull-down driving signal, which controls the pull-down driving unit, by a certain time.

7. A semiconductor memory device, comprising:
a sense amplifier configured to sense and amplify data loaded from a bit line pair;
a power line equalize signal generation unit configured to control an equalizing operation of a power line of the sense amplifier; and
a bit line equalize signal generation unit configured to control an equalizing operation of the bit line pair.

8. A method for operating a semiconductor memory device, the method comprising:
equalizing pull-up and pull-down power lines of a bit line sense amplifier to a precharge voltage until a bit line sense amplifier enable signal is activated after a bit line equalize signal is deactivated; and
applying a driving voltage to the pull-up and pull-down power lines of the bit line sense amplifier in response to the bit line sense amplifier enable signal, and sensing and amplifying a potential difference between a bit line and a bar bit line.
